(19) United States
(12) Patent Application Publication
(10) Pub. No.: US 2023/0187109 A1
(43) Pub. Date: Jun. 15, 2023

(54) IN-PLANE MAGNETIZED FILM, IN-PLANE MAGNETIZED FILM MULTILAYER STRUCTURE, HARD BIAS LAYER, MAGNETORESISTANCE EFFECT ELEMENT, AND SPUTTERING TARGET

(71) Applicant: TANAKA KIKINZOKU KOGYO K.K., Tokyo (JP)

(72) Inventors: Ryousuke KUSHIBIKI, Tsukuba-shi (JP); Kim Kong THAM, Tsukuba-shi (JP); Tomonari KAMADA, Tsukuba-shi (JP)

(73) Assignee: TANAKA KIKINZOKU KOGYO K.K., Tokyo (JP)

(21) Appl. No.: 17/920,865

(22) PCT Filed: Apr. 28, 2021
(86) PCT No.: PCT/JP2021/016941

§ 371 Date: Oct. 24, 2022

(30) Foreign Application Priority Data
May 1, 2020 (JP) 2020-081599

(51) Int. Cl. H01F 10/16; C23C 14/34; C23C 14/16

(52) U.S. Cl. CPC H01F 10/16; C23C 14/165; C23C 14/3414

(57) ABSTRACT

An in-plane magnetized film for use as a hard bias layer of a magnetoresistive effect element contains metal Co, metal Pt, and an oxide and has a thickness of 20 nm or more and 80 nm or less, wherein: the in-plane magnetized film contains the metal Co in an amount of 45 at% or more and 80 at% or less and the metal Pt in an amount of 20 at% or more and 55 at% or less relative to a total of metal components of the in-plane magnetized film; the in-plane magnetized film contains the oxide in an amount of 3 vol% or more and 25 vol% or less relative to a whole amount of the in-plane magnetized film; and the in-plane direction average grain diameter of magnetic crystal grains of the in-plane magnetized film is 15 nm or more and 30 nm or less.

### TECHNICAL FIELD

The present invention relates to an in-plane magnetized film, an in-plane magnetized film multilayer structure, a hard bias layer, a magnetoresistive effect element, and a sputtering target, and more particularly relates to a CoPt-oxide-based in-plane magnetized film, a CoPt-oxide-based in-plane magnetized film multilayer structure, and a hard bias layer having the CoPt-oxide-based in-plane magnetized film or the CoPt-oxide-based in-plane magnetized film multilayer structure, which can achieve magnetic performance of a magnetic coercive force Hc of 2.00 kOe or more and remanent magnetization per unit area Mrt of 2.00 memu/cm² or more without adopting film formation on a heated substrate (hereinafter also referred to as film formation with heating), and also relates to a magnetoresistive effect element and a sputtering target that are related to the CoPt-oxide-based in-plane magnetized film, the CoPt-oxide-based in-plane magnetized film multilayer structure, or the hard bias layer. The CoPt-oxide-based in-plane magnetized film and the CoPt-oxide-based in-plane magnetized film multilayer structure are usable in a hard bias layer of a magnetoresistive effect element.

It is conceivable that a hard bias layer having a magnetic coercive force Hc of 2.00 kOe or more and remanent magnetization per unit area Mrt of 2.00 memu/cm² or more has as much or more magnetic coercive force and remanent magnetization per unit area than a hard bias layer of an existing magnetoresistive effect element. In the present application, “remanent magnetization per unit area” of the in-plane magnetized film refers to the value obtained by multiplying remanent magnetization per unit volume of the in-plane magnetized film by the thickness of the in-plane magnetized film.

In the present application, the hard bias layer refers to a thin-film magnet that applies a bias magnetic field to a magnetic layer exhibiting a magnetoresistive effect (hereinafter also referred to as a free magnetic layer).

In the present application, metal Co may be simply described as Co, metal Pt may be simply described as Pt, and metal Ru may be simply described as Ru. Other metal elements may be described as in the same manner.

In the present application, boron (B) is included in the category of a metal element.

### BACKGROUND ART

Currently, magnetic sensors are used in many fields, and one of the magnetic sensors used commonly is a magnetoresistive effect element.

A magnetoresistive effect element has a magnetic layer exhibiting a magnetoresistive effect (free magnetic layer) and a hard bias layer applying a bias magnetic field to the magnetic layer (free magnetic layer), and the hard bias layer is required to be able to apply a magnetic field of a predetermined strength or more to the free magnetic layer in a stable manner.

Thus, the hard bias layer is required to have a high magnetic coercive force and high remanent magnetization.

However, hard bias layers of existing magnetoresistive elements have a magnetic coercive force of about 2 kOe (for example, FIG. 7 of Patent Literature 1), and so an increase in the magnetic coercive force is desired.

The hard bias layer is also required to have remanent magnetization per unit area of about 2 memu/cm² or more (for example, paragraph 0007 of Patent Literature 2).

There is a technique described in Patent Literature 3 to accommodate thereto. In the technique described in Patent Literature 3, a seed layer (a composite seed layer including a Ta layer and a metal layer, which is formed on the Ta layer and has a face-centered cubic (111) crystal structure or a hexagonal closest packed (001) crystal structure) is provided between a sensor laminate (a laminate having a free magnetic layer) and a hard bias layer so as to orient a magnetic material such that an easy axis is oriented along a longitudinal direction, for the purpose of increasing the magnetic coercive force of the hard bias layer. However, the above-described magnetic characteristics required of the hard bias layer are not satisfied. In this technique, the seed layer provided between the sensor laminate and the hard bias layer needs to be thick in order to increase the magnetic coercive force. Therefore, the structure also has the problem of weakening a magnetic field to be applied to the free magnetic layer in the sensor laminate.

Patent Literature 4 describes use of FePt as a magnetic material to be used in a hard bias layer, the FePt hard bias layer having a Pt or Fe seed layer, and a Pt or Fe capping layer. Patent Literature 4 suggests a structure in which Pt or Fe contained in the seed layer and the capping layer and FePt contained in the hard bias layer are mixed with each other during annealing at an annealing temperature of approximately 250 to 350° C. However, in a heating process required for formation of the hard bias layer, it is necessary to consider effects on other films that have already been stacked. Thus, the heating process is a process to avoid as much as possible.

Patent Literature 5 describes that an annealing temperature can be lowered to about 200° C. by optimization of the annealing temperature. Patent Literature 5 describes that the magnetic coercive force of a hard bias layer is 3.5 kOe or more, but the remanent magnetization per unit area thereof is about 1.2 memu/cm², which does not satisfy the above-described magnetic characteristics required of the hard bias layer.

Patent Literature 6 describes a magnetic recording medium for longitudinal recording, the magnetic layers of which have a granular structure constituted of ferromagnetic crystal grains in a hexagonal closest packed structure and a nonmagnetic grain boundary, which surrounds the ferromagnetic crystal grains and is mainly made of an oxide. There have been no examples of such a granular structure used in a hard bias layer of a magnetoresistive effect element. The technique described in Patent Literature 6 aims at reduction in a signal-to-noise ratio, which is an obj ect of a magnetic recording medium. The magnetic layers are stacked in layers by interposing a nonmagnetic layer between the magnetic layers. The upper and lower magnetic layers are coupled by an antiferromagnetic coupling, and hence have a structure unsuitable for increasing the magnetic coercive force of the magnetic layers.

### CITATION LIST

### Patent Literature

Patent Literature 1: JP2008-283016
Patent Literature 2: JP2008-547150
Patent Literature 3: JP2011-008907
Patent Literature 4: US2009/0274931A1
Patent Literature 5: JP2012-216275
Patent Literature 6: JP2003-178423

### SUMMARY OF INVENTION

### Technical Problem

When the application to an actual magnetoresistive effect element is considered, a sensor laminate (a laminate having a free magnetic layer) and a hard bias layer are preferably made as thin as possible. Also, no film formation with heating is preferably performed.

In order to obtain a hard bias layer having a higher magnetic coercive force than that (about 2 kOe) of hard bias layers of existing magnetoresistive elements and higher remanent magnetization per unit area than that (about 2 memu/cm²) of the hard bias layers of the existing magnetoresistive elements, with the foregoing conditions satisfied, the inventors considered that it was necessary to search for different elements or compounds from elements or compounds used in the existing hard bias layers. The inventors believed that application of an oxide in a CoPt-based in-plane magnetized film might been promising. In contrast, the site that exhibits magnetism in CoPt-oxide-based in in-plane magnetized film is not a crystal grain boundary composed of oxide, but it is a CoPt alloy magnetic crystal grain, and thus the inventors considered that the less the oxide content in CoPt-oxide-based in-plane magnetized film is, the more magnetic coercive force Hc and remanent magnetization per unit area Mrt may improve the magnetic properties.

In consideration of the aforementioned circumstances, an object of the present invention is to provide an in-plane magnetized film, an in-plane magnetized film multilayer structure, and a hard bias layer that can achieve magnetic performance of a magnetic coercive force Hc of 2.00 kOe or more and remanent magnetization per unit area Mrt of 2.00 memu/cm² or more, without adopting film formation with heating. A supplemental object of the present invention is to provide a magnetoresistive element and a sputtering target that are related to the in-plane magnetized film, the in-plane magnetized film multilayer structure, or the hard bias layer.

### Solution to Problem

The present invention has solved the above-described problems by the following in-plane magnetized film, in-plane magnetized film multilayer structure, hard bias layer, magnetoresistive effect element, and sputtering target.

That is, a first aspect of an in-plane magnetized film according to the present invention is an in-plane magnetized film for use as a hard bias layer of a magnetoresistive element. The in-plane magnetized film is characterized by containing metal Co, metal Pt, and an oxide, by having a thickness of 20 nm or more and 80 nm or less, by containing the metal Co in an amount of 45 at% or more and 80 at% or less and the metal Pt in an amount of 20 at% or more and 55 at% or less relative to the total of metal components of the in-plane magnetized film, by containing the oxide in an amount of 3 vol% or more and 25 vol% or less relative to the whole amount of the in-plane magnetized film, and by satisfying a condition that an in-plane direction average grain diameter of magnetic crystal grains of the in-plane magnetized film is 15 nm or more and 30 nm or less.

Here, with respect to in-plane magnetized film according to the present invention and the members such as the substrate film and the like which are present in association with the present invention, the meaning of the term noting the vertical direction shall be interpreted with reference to the condition in which the substrate film on which in-plane magnetized film is laminated is horizontally arranged so that the substrate film is at the lowest position.

Further, “in-plane direction average grain diameter of magnetic crystal grains of the in-plane magnetized film” is calculated by the method described in “ (F) in-plane direction average grain diameter of CoPt alloy magnetic crystal grains in CoPt in-plane magnetized film (Examples 1 to 14, Comparative Examples 1 and 2) ” in the column of “Example”. The same applies to similar descriptions elsewhere in the present application.

The in-plane magnetized film may be configured to have a granular structure constituted of CoPt alloy crystal grains and a crystal grain boundary made of the oxide.

The crystal grain boundary used herein refers to a boundary of the crystal grains.

The oxide may contain at least one of a Ti oxide, a Si oxide, a W oxide, a B oxide, a Mo oxide, a Ta oxide, and a Nb oxide.

The in-plane magnetized film may contain boron in an amount of 0.5 at% or more and 3.5 at% or less relative to a total of metal components of the in-plane magnetized film.

A first aspect of an in-plane magnetized film multilayer structure according to the present invention is an in-plane magnetized film multilayer structure for use as a hard bias layer of a magnetoresistive element, and is characterized in the following points. The in-plane magnetized film multilayer structure has a plurality of in-plane magnetized films and a nonmagnetic intermediate layer the crystal structure of which is a hexagonal closest packed structure, and the nonmagnetic intermediate layer is disposed between the in-plane magnetized films, and the in-plane magnetized films adjacent across the nonmagnetic intermediate layer are coupled by a ferromagnetic coupling. Each of the in-plane magnetized films contains metal Co, metal Pt, and an oxide. Each of the in-plane magnetized films contains the metal Co in an amount of 45 at% or more and 80 at% or less and the metal Pt in an amount of more than 20 at% or more and 55 at% or less relative to the total of metal components of the each of the in-plane magnetized films, and contains the oxide in an amount of 3 vol% or more and 25 vol% or less relative to the whole amount of the each of the in-plane magnetized film. An in-plane direction average grain diameter of magnetic crystal grains of the in-plane magnetized film is 15 nm or more and 30 nm or less, and a total thickness of the plurality of in-plane magnetized films is 20 nm or more.

A second aspect of an in-plane magnetized film multilayer structure according to the present invention is an in-plane magnetized film multilayer structure for use as a hard bias layer of a magnetoresistive effect element, and is characterized in the following points. The in-plane magnetized film multilayer structure has a plurality of in-plane magnetized films and a nonmagnetic intermediate layer, and the nonmagnetic intermediate layer is disposed between the in-plane magnetized films. The in-plane magnetized films adjacent across the nonmagnetic intermediate layer are coupled by a ferromagnetic coupling. Each of the in-plane magnetized films contains metal Co, metal Pt, and an oxide. The each of the in-plane magnetized films contains the metal Co in an amount of 45 at% or more and 80 at% or less and the metal Pt in an amount of 20 at% or more and 55 at% or less relative to a total of metal components of the each of the in-plane magnetized films, and contains the oxide in an amount of 3 vol% or more and 25 vol% or less relative to a whole amount of the each of the in-plane magnetized films. An in-plane direction average grain diameter of magnetic crystal grains of the each of the in-plane magnetized films is 15 nm or more and 30 nm or less, and the in-plane magnetized film multilayer structure has a magnetic coercive force of 2.00 kOe or more and remanent magnetization per unit area of 2.00 memu/cm² or more.

In the present application, the nonmagnetic intermediate layer refers to a nonmagnetic layer disposed between the in-plane magnetized films.

In the present application, the ferromagnetic coupling refers to a coupling based on an exchange interaction produced when spins of magnetic layers (here, the in-plane magnetized films) that are adjacent across the nonmagnetic intermediate layer are in parallel (directed in the same direction).

In the present application, “remanent magnetization per unit area” of the in-plane magnetized film multilayer structure refers to the value obtained by multiplying remanent magnetization per unit volume of the in-plane magnetized films included in the in-plane magnetized film multilayer structure by the total thickness of the in-plane magnetized films included in the in-plane magnetized film multilayer structure.

The nonmagnetic intermediate layer is preferably made of Ru or a Ru alloy.

In the in-plane magnetized film multilayer structure, the in-plane magnetized films may be configured to have a granular structure constituted of CoPt alloy crystal grains and a crystal grain boundary made of the oxide.

In the first aspect and the second aspect of the in-plane magnetized film multilayer structure according to the present invention, the oxide may contain at least one of a Ti oxide, a Si oxide, a W oxide, a B oxide, a Mo oxide, a Ta oxide, and a Nb oxide.

A thickness per one layer of the in-plane magnetized films is typically 5 nm or more and 30 nm or less.

A hard bias layer according to the present invention is a hard bias layer characterized by having the in-plane magnetized film or the in-plane magnetized film multilayer structure.

A magnetoresistive effect element according to the present invention is a magnetoresistive effect element characterized by having the hard bias layer.

A sputtering target according to the present invention is characterized in the following points. The sputtering target is for use in forming an in-plane magnetized film for use as at least part of a hard bias layer of a magnetoresistive element by room temperature film formation. The sputtering target contains metal Co, metal Pt, and an oxide. The sputtering target contains the metal Co in an amount of 50 at% or more and 85 at% or less and the metal Pt in an amount of 15 at% or more and 50 at% or less relative to the total of metal components of the sputtering target, and contains the oxide in an amount of 3 vol% or more and 25 vol% or less relative to the whole amount of the sputtering target. The in-planemagnetized film to be formed using by the sputtering target has a magnetic coercive force of 2.00 kOe or more and remanent magnetization per unit area of 2.00 memu/cm² or more.

### Advantageous Effects of Invention

According to the present invention, it is possible to provide an in-plane magnetized film, an in-plane magnetized film multilayer structure, and a hard bias layer that can achieve magnetic performance of a magnetic coercive force Hc of 2.00 kOe or more and remanent magnetization per unit area Mrt of 2.00 memu/cm² or more, without adopting film formation with heating.

### BRIEF DESCRIPTION OF DRAWINGS

FIG. 1 is a cross-sectional view schematically showing a state in which an in-plane magnetized film 10 according to a first embodiment of the present invention is applied to a hard bias layer 14 of a magnetoresistive effect element 12.

FIG. 2 is a cross-sectional view schematically showing a state in which an in-plane magnetized film multilayer structure 20 according to a second embodiment of the present invention is applied to a hard bias layer 26 of a magnetoresistive element 24.

FIG. 3 is a diagrammatic perspective view schematically showing the form of a thinned sample 80 after being subjected to thinning processing.

FIG. 4 is an example of an observation image of cross-sectional view in a thickness direction (an observation image of reference Example 7) obtained by imaging with a scanning transmission electron microscope.

FIG. 5 is a result of line analysis (elemental analysis) performed in a thickness direction of an in-plane magnetized film of the reference Example 7 (performed along a black line in FIG. 4).

FIG. 6 is an example of an in-plane direction cross-sectional plane observation image obtained by imaging using scanning transmission electron microscope (plane observation image of Example 1).

FIG. 7 is a schematic plane observation image for explaining how to measure average grain diameter.

### DESCRIPTION OF EMBODIMENTS

### First Embodiment

### 1) Outline

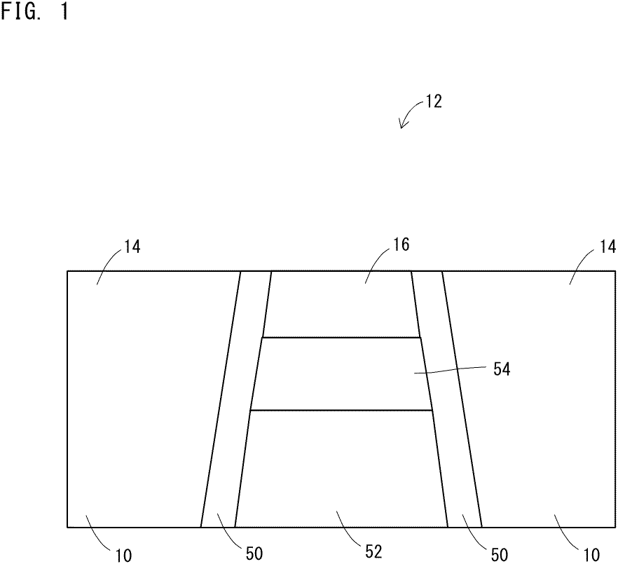

FIG. 1 is a cross-sectional view schematically showing a state in which an in-plane magnetized film 10 according to a first embodiment of the present invention is applied to a hard bias layer 14 of a magnetoresistive element 12. In FIG. 1, a substrate layer (the in-plane magnetized film 10 is formed on the substrate layer) is omitted.

A detailed discussion of the structure shown in FIG. 1 is as follows, with a tunneling magnetoresistive effect element as a magnetoresistive effect element 12 in mind. Note that the in-plane magnetized film 10 according to the first embodiment is not limited to application to a hard bias layer of the tunneling magnetoresistive effect element and is capable of being applied to, for example, a hard bias layer of a giant magnetoresistive effect element or an anisotropic magnetoresistive effect element.

The magnetoresistive effect element 12 (here, the tunneling magnetoresistive effect element) has two ferromagnetic layers (a free magnetic layer 16 and a pinned layer 52) separated by an extremely thin nonmagnetic tunnel barrier layer (hereinafter, a barrier layer 54). The direction of magnetization of the pinned layer 52 is fixed by securing the pinned layer 52 on an adjoining antiferromagnetic layer (not shown) by an exchange coupling, or the like. The direction of magnetization of the free magnetic layer 16 can freely rotate with respect to the direction of magnetization of the pinned layer 52, under the presence of an external magnetic field. Because the rotation of the free magnetic layer 16 with respect to the direction of magnetization of the pinned layer 52 by the external magnetic field causes a change in electric resistance, the detection of the change in the electric resistance allows for the detection of the external magnetic field.

The hard bias layer 14 plays a role in stabilizing a magnetization direction axis of the free magnetic layer 16 by applying a bias magnetic field to the free magnetic layer 16. An insulating layer 50 made of an electrically insulating material plays a role in preventing diversion of a sensor current that flows through a sensor laminate (the free magnetic layer 16, the barrier layer 54, and the pinned layer 52) in a vertical direction into the hard bias layer 14 on both sides of the sensor laminate (the free magnetic layer 16, the barrier layer 54, and the pinned layer 52).

As shown in FIG. 1, the in-plane magnetized film 10 according to the first embodiment is able to be used as the hard bias layer 14 of the magnetoresistive effect element 12 and to apply the bias magnetic field to the free magnetic layer 16, which exhibits a magnetoresistance effect. The hard bias layer 14 is composed of only the in-plane magnetized film 10 according to the first embodiment, and thus, is constituted of a single layer of the in-plane magnetized film 10.

The in-plane magnetized film 10 according to the first embodiment is a single-layer in-plane magnetized film that contains an oxide and has as much or more magnetic coercive force (a magnetic coercive force of 2.00 kOe or more) and remanent magnetization per unit area (2.00 memu/cm² or more) as compared with those of the hard bias layers of existing magnetoresistive elements. To be more specific, the in-plane magnetized film 10 according to the first embodiment is a CoPt-oxide-based in-plane magnetized film that contains metal Co, metal Pt, and an oxide, that contains the metal Co in an amount of 45 at% or more and 80 at% or less and the metal Pt in an amount of 20 at% or more and 55 at% or less relative to the total of metal components of the in-plane magnetized film, that contains the oxide in an amount of 3 vol% or more and 25 vol% or less relative to the whole amount of the in-plane magnetized film, and that has a thickness of 20 nm or more and 80 nm or less.

### 2) Components of In-Plane Magnetized Film 10

As described above, the in-plane magnetized film 10 according to the first embodiment contains Co and Pt as metal components, and also contains an oxide.

The metal Co and the metal Pt become components of magnetic crystal grains (minute magnets) in the in-plane magnetized film to be formed by sputtering.

Cobalt is a ferromagnetic metallic element, and plays a dominant role in forming the magnetic crystal grains (minute magnets) in the in-plane magnetized film. From the viewpoint of increasing a crystal magnetic anisotropy constant Ku of CoPt alloy crystal grains (magnetic crystal grains) in the in-plane magnetized film obtained by sputtering and also from the viewpoint of maintaining the magnetization of the CoPt alloy crystal grains (magnetic crystal grains) in the in-plane magnetized film obtained, the content ratio of Co in the in-plane magnetized film according to the present embodiment is set at 45 at% or more and 80 at% or less relative to the total of metal components of the in-plane magnetized film. From the similar viewpoint, the content ratio of Co in the in-plane magnetized film according to the present embodiment is preferably 45 at% or more and 70 at% or less, and more preferably 45 at% or more and 60 at% or less, relative to the total of the metal components of the in-plane magnetized film.

Platinum is alloyed with Co in a predetermined composition range to have the function of reducing the magnetic moment of the alloy. As a result, it plays a role in controlling the strength of magnetism of the magnetic crystal grains. Moreover, Pt has the function of increasing a magnetic coercive force of the in-plane magnetized film by increasing a crystal magnetic anisotropy constant Ku of the CoPt alloy crystal grains (magnetic crystal grains) in the in-plane magnetized film obtained by sputtering. From the viewpoint of increasing the magnetic coercive force of the in-plane magnetized film and also from the viewpoint of controlling the magnetism of the CoPt alloy crystal grains (magnetic crystal grains) in the in-plane magnetized film, the content ratio of Pt in the in-plane magnetized film according to the present embodiment is set at 20 at% or more and 55 at% or less relative to the total of the metal components of the in-plane magnetized film. From the similar viewpoint, the content ratio of Pt in the in-plane magnetized film according to the present embodiment is preferably 30 at% or more and 55 at% or less, and more preferably 40 at% or more and 55 at% or less, relative to the total of the metal components of the in-plane magnetized film.

Further, as metal component of the in-plane magnetized film 10 according to the present embodiment, in addition to Co and Pt, boron B may be contained in an amount of 0.5 at% or more and 3.5 at% or less. As demonstrated in the examples to be described later, magnetic coercive force Hc of the in-plane magnetized film 10 can be further improved by containing boron B in an amount of 0.5 at% or more and 3.5 at% or less.

The oxide contained in the in-plane magnetized film 10 according to the first embodiment contains at least one of a Ti oxide, a Si oxide, a W oxide, a B oxide, a Mo oxide, a Ta oxide, and a Nb oxide. In the in-plane magnetized film 10, a nonmagnetic material made of an oxide such as those described above partitions the CoPt alloy magnetic crystal grains to form a granular structure. That is, the granular structure is constituted of the CoPt alloy crystal grains and a crystal grain boundary of the oxide surrounding the CoPt alloy crystal grains.

Accordingly, an increase in the content of the oxide in the in-plane magnetized film 10 is preferable because it can facilitate reliable partitioning among the magnetic crystal grains and the independence of the magnetic crystal grains from one another. From this viewpoint, the content of the oxide in the in-plane magnetized film 10 according to the first embodiment (the average value of the content of the oxide in the entire in-plane magnetized film 10) is typically set at an amount of 3 vol% or more. From the same viewpoint, the content of the oxide in the in-plane magnetized film 10 according to the first embodiment (the average value of the content of the oxide in the entire in-plane magnetized film 10) is preferably 4 vol% or more, and more preferably 5 vol% or more.

However, if the content of the oxide in the in-plane magnetized film 10 (the average value of the content of the oxide in the entire in-plane magnetized film 10) is too high, the oxide mixed in the CoPt alloy crystal grains (magnetic crystal grains) might have an adverse effect on crystallinity of the CoPt alloy crystal grains (magnetic crystal grains), and the ratio of structures other than a hcp might increase in the CoPt alloy crystal grains (magnetic crystal grains). From this viewpoint, the content of the oxide in the in-plane magnetized film 10 according to the first embodiment (the average value of the content of the oxide in the entire in-plane magnetized film 10) is typically set at 25 vol% or less. From the same viewpoint, the content of the oxide in the in-plane magnetized film 10 according to the first embodiment is preferably 21 vol% or less, and more preferably 16 vol% or less.

Accordingly, in the first embodiment, the content of the oxide in the in-plane magnetized film 10 (the average value of the content of the oxide in the entire in-plane magnetized film 10) is typically set at 3 vol% or more and 25 vol% or less, and the content of the oxide in the in-plane magnetized film 10 according to the first embodiment (the average value of the content of the oxide in the entire in-plane magnetized film 10) is preferably 4 vol% or more and 21 vol% or less, and more preferably 5 vol% or more and 16 vol% or less.

Also, because containing WO₃ or MoOs as the oxide brings about an increase in a magnetic coercive force Hc of the in-plane magnetized film 10, WO₃ or MoOs is preferably contained as the oxide.

Note that in the existing in-plane magnetized films, since a single element such as Cr, W, Ta, or B is used as a grain boundary material for partitioning CoPt alloy crystal grains (magnetic crystal grains), it is conceivable that the grain boundary material forms a solid solution in a CoPt alloy to some extent. Thus, the CoPt alloy crystal grains (magnetic crystal grains) in the current in-plane magnetization film are considered to be adversely affected in crystallinity, resulting in reducing the saturation magnetization and the remanent magnetization, and values of the coercive force Hc and the remanent magnetization of the existing in-plane magnetization film are considered to be adversely affected.

In contrast, in the in-plane magnetized film 10 according to the first embodiment, since a grain boundary material is made of the oxide, the grain boundary material is unlikely to form a solid solution in the CoPt alloy, as compared with a case where the grain boundary material is the single element such as Cr, W, Ta, or B. Therefore, the saturation magnetization and the remanent magnetization of the CoPt alloy crystal grains (magnetic crystal grains) in the in-plane magnetized film 10 according to the first embodiment increase, and hence the in-plane magnetized film 10 according to the first embodiment has an increased magnetic coercive force Hc and an increased remanent magnetization.

### 3) Thickness of In-Plane Magnetized Film 10

When an in-plane magnetized film 10 become thinner, the remanent magnetization per unit area Mrt tends to reduce, and when an in-plane magnetized film 10 become thicker, the coercive force Hc tends to reduce. Therefore, the thickness of the in-plane magnetized film 10 is typically set 20 nm or more and 80 nm or less.

### 4) In-Plane Direction Average Grain Diameter of CoPt Alloy Magnetic Crystal Grains in the In-Plane Magnetized Film 10

When an in-plane direction average grain diameter of CoPt alloy magnetic crystal grains in the in-plane magnetized film 10 become larger, a value of (the length in the in-plane direction of a CoPt alloy magnetic crystal grain)/(the length in the film thickness direction of the CoPt alloy magnetic crystal grain) increases, and the shape of the CoPt alloy magnetic crystal grain in the in-plane magnetized film 10 becomes flatter. This weakens the antimagnetic field in the in-plane direction due to shape magnetic anisotropy, and improves the coercive force Hc of the in-plane magnetized film 10.

Further, when the in-plane direction average grain diameter of magnetic crystal grains of the in-plane magnetized film 10 is large, the volume fraction of a crystal grain boundary to the entire in-plane magnetized film 10 is reduced, and the volume fraction of the CoPt alloy magnetic crystal grains in in-plane magnetized film 10 is increased. Consequently, the saturation magnetization Ms is improved, and remanent magnetization Mr is improved, and thus remanent magnetization per unit area Mrt is improved.

Therefore, from the viewpoint of increasing the coercive force Hc and the remanent magnetization per unit area Mrt of the in-plane magnetized film 10, the in-plane direction average grain diameter of magnetic crystal grains of the in-plane magnetized film 10 is typically 15 nm or more, is preferably 18 nm or more, and is more preferably 20 nm or more.

In contrast, as shown in Examples and Comparative Examples to be described later, the upper limit of the in-plane direction average grain diameter of the CoPt alloy magnetic crystal grains in the in-plane magnetized film 10 is 30 nm because it was not possible to obtain an in-plane magnetized film 10 in which CoPt alloy magnetic crystal grains have an in-plane direction average grain diameter of more than 30 nm.

As the in-plane direction average grain diameter of the CoPt alloy magnetic grains in the in-plane magnetized film 10 increases, the volume of the crystal grain boundary in the in-plane magnetized film 10 decreases, thereby reducing the amount of oxide required in the in-plane magnetized film 10.

### 5) Substrate Film

As a substrate film used in forming the in-plane magnetized film 10 according to the first embodiment, a substrate film that is made of metal Ru or a Ru alloy having the same crystal structure (hexagonal closest packed structure hcp) as that of the magnetic grains (CoPt alloy grains) of the in-plane magnetized film 10 is suitable. Hereinafter, a substrate film that is made of metal Ru or a Ru alloy may be referred to as a Ru-based substrate film. A Ru-based substrate film has an uneven surface, when performing sputtering with CoPt-oxide sputtering target, metal components are easily deposited on the convex portion, and oxide is easily deposited in the concave portion. The metal easily solidifies in the convex part of the substrate film because the concave part of the substrate film is in shadow when viewed from the sputtering particles flying into the substrate film, and the oxide is therefore deposited in the concave part of the substrate film.

Therefore, when the size of the convex portion of the surface of the Ru-based substrate film is large, the size of CoPt alloy magnetic crystal grains grown on the convex portion of the Ru-based substrate film tends to increase. In addition, as describedin “ (1-4) In-plane direction average grain diameter of CoPt alloy magnetic crystal grains in the in-plane magnetized film 10”, it is possible to increase magnetic coercive force Hc and remanent magnetization per unit area Mrt by increasing the in-plane direction average grain diameter of CoPt alloy magnetic crystal grains in the in-plane magnetized film 10. Therefore, it is preferable to use a Ru-based substrate film which has the large size of the convex portion of the surface when forming the in-plane magnetized film 10 according to the first embodiment. In the Ru-based substrate film, as long as the thickness is about 20 nm or more, the size of the convex portion of the surface becomes large to some extent, so that the Ru-based substrate film having a thickness of 20 nm or more is preferably used, the Ru-based substrate film having a thickness of 25 nm or more is more preferably used, and the Ru-based substrate film having a thickness of 30 nm or more is particularly preferably used.

In order to ensure an orderly in-plane orientation of the magnetic crystal grains (CoPt alloy grains) in the in-plane magnetized film 10 to be stacked, it is preferable that a lot of (10.0) planes or (11.0) planes are disposed on a surface of a Ru substrate film or a Ru alloy substrate film to be used.

The substrate film used in forming the in-plane magnetized film according to the present invention is not limited to the Ru substrate film or the Ru alloy substrate film, but any substrate film is usable as long as the substrate film is able to give the in-plane orientation of the CoPt magnetic crystal grains and to promote magnetic separation of the CoPt magnetic crystal grains in the obtained in-plane magnetized film, and is suitable for increasing the in-plane direction average grain diameter of CoPt alloy magnetic crystal grains in the in-plane magnetized film 10.

### 6) Sputtering Target

A sputtering target used in producing the in-plane magnetized film 10 according to the first embodiment is a sputtering target that is used in producing the in-plane magnetized film 10 by room temperature film formation, where the in-plane magnetized film 10 is used as at least part of the hard bias layer 14 of the magnetoresistive element 12. The sputtering target contains metal Co, metal Pt, and an oxide. The sputtering target contains the metal Co in an amount of 50 at% or more and 85 at% or less and the metal Pt in an amount of 15 at% or more and 50 at% or less relative to the total of metal components of the sputtering target, and contains the oxide in an amount of 3 vol% or more and 25 vol% or less relative to the whole amount of the sputtering target. The in-planemagnetized film to be formed has a magnetic coercive force of 2.00 kOe or more, and remanent magnetization per unit area of 2.00 memu/cm² or more. As described in “ (E) Analysis of composition of in-plane magnetized film (Reference Examples 1 to 8)” later, there is a deviation between the actual composition (composition obtained by an analysis of composition) of the produced CoPt-oxide-based in-plane magnetized film and the composition of the sputtering target used in producing the CoPt-oxide-based in-plane magnetized film, and so the composition range of each element contained in the above-described sputtering target does not coincide with the composition range of each element contained in the in-plane magnetized film 10 according to the first embodiment.

A description about components (metal Co, metal Pt, and an oxide) of the sputtering target is the same as that about the components of the in-plane magnetized film described in the above-described “ (1-2) Components of in-plane magnetized film 10”, and so the description is omitted.

### 7) Method for Forming In-Plane Magnetized Film 10

The in-plane magnetized film 10 according to the first embodiment is formed on a predetermined substrate film (the substrate film described in the above-described “(1-5) Substrate film”) by sputtering using a sputtering target described in the above-described “(1-6) Sputtering target”. Note that, heating is unnecessary in this film formation process, and the in-plane magnetized film 10 according to the first embodiment can be formed by room temperature film formation.

### Second Embodiment

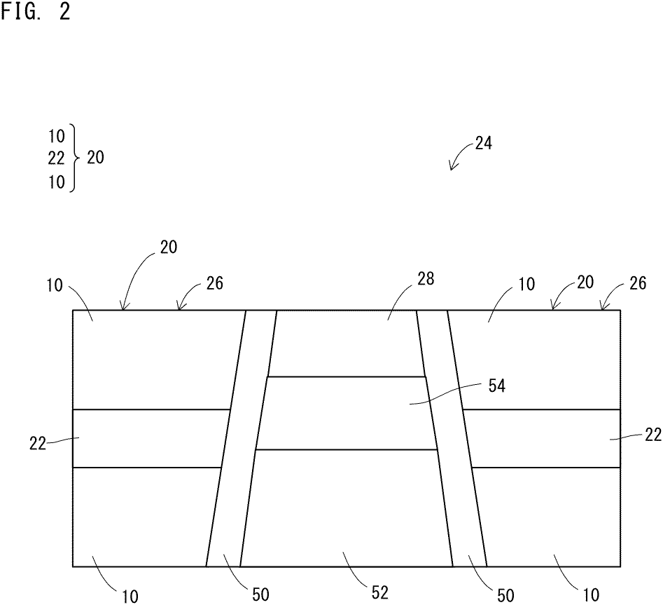

FIG. 2 is a cross-sectional view schematically showing a state in which an in-plane magnetized film multilayer structure 20 according to a second embodiment of the present invention is applied to a hard bias layer 26 of a magnetoresistive element 24.

Hereinafter, the in-plane magnetized film multilayer structure 20 according to the second embodiment will be described, but the components of the in-plane magnetized film 10, the thickness of the in-plane magnetized film 10, the in-plane direction average grain diameter of CoPt alloy magnetic crystal grains in the in-plane magnetized film 10, the substrate film that is used in producing the in-plane magnetized film 10, the sputtering target that is used in producing the in-plane magnetized film 10, and the method for forming the in-plane magnetized film 10 have already been described in “(1) First Embodiment”, and descriptions thereof are omitted.

As shown in FIG. 2, the in-plane magnetized film multilayer structure 20 according to the second embodiment of the present invention includes a nonmagnetic intermediate layer 22 on an in-plane magnetized film 10 according to the first embodiment, and an in-plane magnetized film 10 is stacked on the nonmagnetic intermediate layer 22. Although only two layers of the in-plane magnetized film 10 are stacked in FIG. 2, three or more layers of in-plane magnetized films 10 may be stacked with a nonmagnetic intermediate layer 22 interposed therebetween.

In the in-plane magnetized film multilayer structure 20, the thickness per one layer of the in-plane magnetized films 10 is typically 5 nm or more and 30 nm or less. The thickness per one layer of the in-plane magnetized films 10 in the in-plane magnetized film multilayer structure 20 is preferably 5 nm or more and 15 nm or less, and more preferably 10 nm or more and 15 nm or less, from the viewpoint of increasing the magnetic coercive force Hc more. The total of thicknesses of the in-plane magnetized film 10 is typically set to 20 nm or more from the viewpoint of adjusting the remanent magnetization per unit area Mrt to be 2.00 meum/cm² or more. Further, with respect to the upper limit of the total of thicknesses of the in-plane magnetized films 10, as will be described later, the adjacent in-plane magnetized films 10 separated by the interposition of the nonmagnetic intermediate layer 22 are coupled via a ferromagnetic coupling, and so, even if the total of thicknesses of the in-plane magnetized film 10 increases, the magnetic coercive force Hc does not decrease in theory, and there is no upper limit. Actually, it is confirmed by examples described later that the magnetic coercive force Hc is kept at 2.00 kOe or more at least when the total of thicknesses of in-plane magnetized films 10 is up to 60 nm.

The in-plane magnetized film multilayer structure 20 according to the second embodiment can be used as the hard bias layer 26 of the magnetoresistive element 24, so that it is possible to apply a bias magnetic field to a free magnetic layer 28 exhibiting a magnetoresistive effect.

The nonmagnetic intermediate layer 22 is interposed between the in-plane magnetized films 10, so as to play a role in separating the in-plane magnetized films 10 and multilayering the in-plane magnetized films. Multilayering the in-plane magnetized films with the nonmagnetic intermediate layer 22 interposed therebetween can further increase the magnetic coercive force Hc while maintaining the value of the remanent magnetization per unit area Mrt.

The adjacent in-plane magnetized films 10 separated with the nonmagnetic intermediate layer 22 interposed therebetween are disposed so that spins are in parallel (directed in the same direction). Since disposing them in this manner allows the adjacent in-plane magnetized films 10 separated by the interposition of the nonmagnetic intermediate layer 22 to be coupled by a ferromagnetic coupling, the in-plane magnetized film multilayer structure 20 can increase the magnetic coercive force Hc and can exhibit a good magnetic coercive force Hc while maintaining the value of the remanent magnetization per unit area Mrt.

The metal used in the non-magnetic intermediate layer 22 is metal having the same crystal structure as those of CoPt alloy magnetic crystal grains (hexagonal closest packed structure hcp) from the viewpoint of not impairing the crystal structure of the CoPt alloy magnetic crystal grains. Specifically, as the non-magnetic intermediate layer 22, there may be suitably used metal Ru or a Ru alloy, which has the same crystal structure as the crystal structure of the CoPt alloy magnetic crystal grains in the in-plane magnetized film 10 (hexagonal closest packed structure hcp).

Specific examples of the additive element when the metal used in the non-magnetic intermediate layer 22 is a Ru alloy may include Cr, Pt, and Co. The added amount of those metals is preferably in a range in which the Ru alloy takes a hexagonal closest packed structure hcp.

Bulk samples of a Ru alloy were produced by performing an arc welding, and X-ray diffraction peaks were analyzed by an X-ray diffraction device (XRD: SmartLab manufactured by Rigaku Corporation). In a RuCr alloy, when the added amount of Cr was 50 at%, a mixed phase of the hexagonal closest packed structure hcp and RuCr₂ was confirmed. Thus, when a RuCr alloy is used for the nonmagnetic interlayer 22, the added amount of Cr is suitably less than 50 at%, preferably less than 40 at%, and more preferably less than 30 at%. In a RuPt alloy, when the added amount of Pt was 15 at%, a mixed phase of the hexagonal closest packed structure hcp and a face-centered cubic structure fcc derived from Pt was confirmed. Thus, when a RuPt alloy is used for the nonmagnetic interlayer 22, the added amount of Pt is suitably less than 15 at%, preferably less than 12.5 at%, and more preferably less than 10 at%. In a RuCo alloy, regardless of the added amount of Co, the RuCo alloy forms the hexagonal closest packed structure hcp, but when adding Co in an amount of 40 at% or more, the RuCo alloy becomes a magnetic material. Thus, the added amount of Co is suitably less than 40 at%, preferably less than 30 at%, and more preferably less than 20 at%.

The thickness of the nonmagnetic intermediate layer 22 is typically 0.3 nm or more and 3 nm or less.

### EXAMPLES

Examples, Comparative Examples, and Reference Examples will be hereinafter described to verify the present invention.

In the following (A), in CoPt-WOs in-plane magnetized film single-layer structures, the effect of an in-plane direction average grain diameter of magnetic crystal grains in the in-plane magnetized film on magnetic coercive force Hc and remanent magnetization per unit area Mrt is studied; in the following (B), in CoPt-WOs in-plane magnetized film multilayer structures, the effect of an in-plane direction average grain diameter of magnetic crystal grains in the in-plane magnetized film on magnetic coercive force Hc and remanent magnetization per unit area Mrt is studied; and in the following (C), in CoPt-WOs in-plane magnetized film multilayer structures, the effect of the content of oxide in the in-plane magnetized film on magnetic coercive force Hc and remanent magnetization per unit areaMrt is studied. In addition, in the following (D), in CoPt-oxide in-plane magnetized film multilayer structures, magnetic coercive force Hc and remanent magnetization per unit area Mrt are measured when oxide in an in-plane magnetized film 10 is set to B₂O₃ and when boron B is added as a metal component of an in-plane magnetized film 10.

In the following (E), analysis of composition was performed on CoPt-WOs in-plane magnetized films according to Reference Examples 1 to 8 in order to check the degree of a deviation between the actual composition (composition obtained by the analysis of composition) of a produced CoPt-WOs in-plane magnetized film and the composition of a sputtering target used in producing the CoPt-WOs in-plane magnetized film. As a result, it was found out that a deviation occurred between the composition of a produced in-plane magnetized film and the composition of the sputtering target used in producing the in-plane magnetized film.

In-plane magnetized film composition of CoPt-oxide in Examples and Comparative Examples described in (A) to (D) below was calculated by performing calculations for correcting the deviation of the composition found in (E) below on the composition of sputtering target used in the preparation.

In addition, the following (F) specifically explains how to measure an in-plane direction average grain diameter of magnetic crystal grains in the in-plane magnetized film.

### (A) Study About the Effect of an In-Plane Direction Average Grain Diameter of Magnetic Crystal Grains in the In-Plane Magnetized Film on Magnetic Coercive Force Hc and Remanent Magnetization Per Unit AreaMrt in CoPt-WOs In-Plane Magnetized Film Single-Layer Structures (Example 1 and Comparative Example 1)

In Example 1 and Comparative Example 1, (Co-30Pt)-10vol%WO₃ sputtering target was used to produce (Co-34.7Pt)-11.0vol%WO₃ in-plane magnetized film single-layer structures having a thickness of 30 nm. A thickness of a Ru substrate layer used in Example 1 is 30 nm and a thickness of a Ru substrate layer used in Comparative Example 1 is 10 nm. A magnetic coercive force Hc, remanent magnetization per unit area Mrt, and an in-plane direction average grain diameter of magnetic crystal grains in the in-plane magnetized film were measured for the (Co-34.7Pt)-11.0vol%WO₃ single-layer structures produced in Example 1 and Comparative Example 1.

The following is a specific explanation.

First, a Ru substrate film was formed on a Si substrate using ES-3100W manufactured by EIKO ENGINEERING, LTD. by sputtering so as to have a thickness of 30 nm (Example 1) and 10 nm (Comparative Example 1). Note that, in any film formation (any film formation of a Ru substrate film, a CoPt in-plane magnetized film, and a Ru nonmagnetic intermediate layer) in Examples and Comparative Examples of the present application, a sputtering apparatus used in sputtering is ES-3100Wmanufacturedby EIKO ENGINEERING, LTD., and a description of the name of the apparatus will be omitted hereinbelow.

In Example 1, a (Co-34.7Pt)-11.OvollWOs in-plane magnetized film single-layer structure having a thickness of 30 nm was formed on a Ru substrate film having a thickness of 30 nm by a sputtering method using (Co-30Pt)-10vol%WO₃ sputtering target, and in Comparative Example 1, a (Co-34.7Pt)-11.0vol%WO₃ in-plane magnetized film single-layer structure having a thickness of 30 nm was formed on a Ru substrate film having a thickness of 10 nm by a sputtering method using (Co-30Pt) -10vol%WO₃ sputtering target.

In these film formation processes (film formation processes of a Ru substrate film and a CoPt in-plane magnetized film), none of them were subjected to substrate heating. They were performed in room temperature film formation.

A hysteresis loop of each of the produced in-plane magnetized film single-layer structures in Example 1 and Comparative Example 1 was measured using a vibrating magnetometer (VSM: TM-VSM211483-HGC manufactured by TAMAKAWA CO., LTD.) (hereinafter referred to as a vibrating magnetometer). From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized film, remanent magnetization per unit area Mrt (memu/cm²) of the produced in-plane magnetized film single-layer structure was calculated.

Further, in in-plane magnetized film single-layer structures of Example 1 and Comparative Example 1, the in-plane direction average grain diameter of CoPt alloy magnetic crystal grains in the CoPt in-plane magnetized film was measured by the measuring method described in (F) below.

The results of Example 1 and Comparative Example 1 are shown in the following Table 1.

TABLE 1

| | Composition of target used for producing in-plane magnetized film | Composition of in-plane magnetized film | Thickness of in-plane magnetized film (nm) | Thickness of Ru substrate film (nm) | In-plane direction average grain diameter of CoPt alloy magnetic crystal grains (nm) | Magnetic coercive force He (kOe) | Remanent magnetization per unit area Mrt (memu/cm²) |
|---|---|---|---|---|---|---|---|
| Example 1 | (Co-30Pt) -10vol%WO₃ | (Co-34.7Pt) -11.0vol%WO₃ | 30 | 30 | 20.4 | 4.05 | 2.02 |
| Comparative Example 1 | (Co-30Pt) -10vol%WO₃ | (Co-34.7Pt)-11.0vol%WO₃ | 30 | 10 | 11.4 | 1.81 | 1.31 |

As can be seen from Table 1, the in-plane magnetized film of Example 1 is the in-plane magnetized film having metal Co, metal Pt, and an oxide, and having a thickness of 30 nm. The in-plane magnetized film contains the metal Co in an amount of 45 at% or more and 80 at% or less and the metal Pt in an amount of 20 at% or more and 55 at% or less relative to a total of metal components (Co, Pt) of the in-plane magnetized film, and contains the oxide in an amount of 3 vol% or more and 25 vol% or less relative to a whole amount of the in-plane magnetized film. The in-plane direction average grain diameter of CoPt alloy magnetic crystal grains of the CoPt in-plane magnetized film is 20.4 nm, which is included in the range of 15 nm or more and 30 nm or less. Therefore, the in-plane magnetized film of Example 1 is within the scope of the present invention, and achieved magnetic performance of a magnetic coercive force Hc of 2.00 kOe or more and remanent magnetization per unit area Mrt of 2.00 memu/cm² or more by the room temperature film formation without heating the substrate.

In contrast, the in-plane magnetized film of Comparative Example 1 has the same composition and thickness as the in-plane magnetized film of Example 1, but the in-plane direction average grain diameter of CoPt alloy magnetic crystal grains of the in-plane magnetized film of Comparative Example 1 is 11.4 nm, which is not included in the range of 15 nm or more and 30 nm or less, and the in-plane magnetized film of Comparative Example 1 is not within the scope of the present invention. The in-plane magnetized film of Comparative Example 1 has a magnetic coercive force Hc of 1.81 kOe, which is less than 2.00 kOe, and has remanent magnetization per unit area Mrt of 1.31 memu/cm², which is less than 2.00 memu/cm². It is considered that, because the in-plane direction average grain diameter of CoPt alloy magnetic crystal grains of the in-plane magnetized film of Comparative Example 1 is as small as 11.4 nm, a magnetic coercive force Hc and remanent magnetization per unit area Mrt became small.

### (B) Study About the Effect of an In-Plane Direction Average Grain Diameter of Magnetic Crystal Grains in the In-Plane Magnetized Film on Magnetic Coercive Force Hc and Remanent Magnetization per Unit AreaMrt in CoPt-WOs In-Plane Magnetized Film Multilayer Structures (Examples 2 and 3 and Comparative Example 2)

An in-plane magnetized film multilayer structure formed in each of Examples 2 and 3 and Comparative Example 2 is a multilayer structure in which CoPt-WOs in-plane magnetized films having a thickness of 15 nm are stacked in four layers sandwiching a Ru nonmagnetic intermediate layer having a thickness of 2 nm. The thickness of the Ru substrate film used is changed to 30 nm (Example 2), 100 nm (Example 3), and 10 nm (Comparative Example 1), and experimental data are obtained in Examples 2 and 3 and Comparative Example 2 in such a manner that in-plane direction average grain diameter of CoPt alloy magnetic crystal grains in the in-plane magnetized film of each of in-plane magnetized film multilayer structures of Examples 2 and 3 and Comparative Example 2 is different.

The following is a specific explanation.

First, Ru substrate films were formed on Si substrates by sputtering so as to have a thickness of 30 nm (Example 2), 100 nm (Example 3), and 10 nm (Comparative Example 1).

A (Co-34.7Pt) -11. 0vol%WO₃ in-plane magnetized film was formed on the formed Ru substrate film by sputtering so as to have a thickness of 15 nm, and a Ru nonmagnetic intermediate layer was formed on the formed (Co-34.7Pt) -11.0vol%WO₃ in-plane magnetized film having a thickness of 15 nm by sputtering (using a sputtering target of 100 at% Ru) so as to have a thickness of 2 nm, and a (Co-34.7Pt) -11. 0vol%WO₃ in-plane magnetized film was formed on the formed Ru nonmagnetic intermediate layer having a thickness of 2 nm by sputtering so as to have a thickness of 15 nm. The above operation was repeated to produce an in-plane magnetized film multilayer structure in which CoPt in-plane magnetized films of a predetermined composition are stacked in four layers.

In these film formation processes (film formation processes of a Ru substrate film, a CoPt in-plane magnetized film, and a Ru nonmagnetic intermediate layer), none of them were subjected to substrate heating. They were performed in room temperature film formation.

A hysteresis loop of each of the produced in-plane magnetized film multilayer structures in Examples 2 and 3 and in Comparative Example 2 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the produced CoPt in-plane magnetized films, remanent magnetization per unit area Mrt (memu/cm²) of the produced CoPt in-plane magnetized film multilayer structure was calculated.

Further, in in-plane magnetized film multilayer structures of Examples 2 and 3 and Comparative Example 2, the in-plane direction average grain diameter of CoPt alloy magnetic crystal grains in the CoPt in-plane magnetized film which is a fourth film counted from the Si substarate side was measured by the measuring method described in (F) below.

The results of Examples 2 and 3 and Comparative Example 2 are shown in the following Table 2.

TABLE 2

| | Composition of target used for producing nonmagnetic intermediate layer | Thickness of nonmagnetic intermediate layer (nm) | Composition of target used for producing in-plane magnetized film | Composition of in-plane magnetized film | Thickness of in-plane magnetized film (nm) | | Thickness of Ru substrate film (nm) | In-plane direction average grain diameter of CoPt alloy magnetic crystal grains (nm) | Magnetic coercive force He (k0e) | Remanent magnetization per unit area Mrt (memu/cm²) |
|---|---|---|---|---|---|---|---|---|---|---|
| | | | | | Total thickness | Thickness of one layer | | | | |
| Example 2 | 100Ru | 2.0 | (Co-30Pt) -10vol%WO₃ | (Co-34.7Pt) -11.0vol%WO₃ | 60 | 15 | 30 | 18.9 | 2.84 | 3.64 |
| Example 3 | 100Ru | 2.0 | (Co-30Pt) -10vol%WO₃ | (Co-34.7Pt) -11.0vol%WO₃ | 60 | 15 | 100 | 22.3 | 5.13 | 3.01 |
| Comparative Example 2 | 100Ru | 2.0 | (Co-30Pt) -10vol%WO₃ | (Co-34.7Pt) -11.0vol%WO₃ | 60 | 15 | 10 | 10.8 | 1.27 | 2.36 |

As can be seen from Table 2, each of in-plane magnetized film multilayer structures of Examples 2 and 3 is an in-plane magnetized film multilayer structure in which CoPt in-plane magnetized films having a thickness of 15 nm are stacked in four layers sandwiching a Ru nonmagnetic intermediate layer having a thickness of 2 nm. Each of the in-plane magnetized films of the in-plane magnetized film multilayer structures of Examples 2 and 3 contains the metal Co in an amount of 45 at% or more and 80 at% or less and the metal Pt in an amount of 20 at% or more and 55 at% or less relative to a total of metal components (Co, Pt) of the each of the in-plane magnetized films, and contains the oxide in an amount of 3 vol% or more and 25 vol% or less relative to a whole amount of the each of the in-plane magnetized film. The in-plane direction average grain diameter of CoPt alloy magnetic crystal grains of the CoPt in-plane magnetized film is 18.9 nm and 22.3 nm, each of which is included in the range of 15 nm or more and 30 nm or less. Therefore, the in-plane magnetized film multilayer structures of Examples 2 and 3 are within the scope of the present invention, and achieved magnetic performance of a magnetic coercive force Hc of 2.00 kOe or more and remanent magnetization per unit area Mrt of 2.00 memu/cm² or more by the room temperature film formation without heating the substrate.

In contrast, the in-plane magnetized film of the in-plane magnetized film multilayer structure of Comparative Example 2 has the same composition, thickness, and number of layers as the in-plane magnetized films of the in-plane magnetized film multilayer structures of Examples 2 and 3, but the in-plane direction average grain diameter of CoPt alloy magnetic crystal grains of the in-plane magnetized film of the in-plane magnetized film multilayer structure of Comparative Example 2 is 10.8 nm, which is not included in the range of 15 nm or more and 30 nm or less, and the in-plane magnetized film multilayer structure of Comparative Example 2 is not within the scope of the present invention. The in-plane magnetized film multilayer structure of Comparative Example 2 has a magnetic coercive force Hc of 1.27 kOe, which is less than 2.00 kOe. It is considered that, because the in-plane direction average grain diameter of CoPt alloy magnetic crystal grains in the in-plane magnetized film of the in-plane magnetized film multilayer structure of Comparative Example 2 is as small as 10.8 nm, a magnetic coercive force Hc became small.

### (C) Study About the Effect of a Content of Oxide in the In-plane Magnetized Film on Magnetic Coercive Force Hc and Remanent Magnetization Per Unit AreaMrt in CoPt-WOs In-Plane Magnetized Film Multilayer Structures (Examples 4 to 11 and 14)

An in-plane magnetized film multilayer structure formed in each of Examples 4 to 11 and 14 is a multilayer structure in which CoPt-WOs in-plane magnetized films having a thickness of 15 nm are stacked in four layers sandwiching a Ru nonmagnetic intermediate layer having a thickness of 2 nm. In Examples 4 to 11 and 14, experimental data were obtained by varying the content of oxide (WO₃) of the CoPt-WOs in-plane magnetized film in the in-plane magnetized film multilayer structures from 3.0 vol% to 20.6 vol%.

The following is a specific explanation.

First, Ru substrate films were formed on Si substrates by sputtering so as to have a thickness of 60 nm.

A CoPt-WOs in-plane magnetized film was formed on the formed Ru substrate film by sputtering so as to have a thickness of 15 nm, and a Ru nonmagnetic intermediate layer was formed on the formed CoPt-WOs in-plane magnetized film having a thickness of 15 nm by sputtering (using a sputtering target of 100 at% Ru) so as to have a thickness of 2 nm, and a CoPt-WOs in-plane magnetized film was formed on the formed Ru nonmagnetic intermediate layer having a thickness of 2 nm by sputtering so as to have a thickness of 15 nm. The above operation was repeated to produce an in-plane magnetized film multilayer structure in which CoPt-WOs in-plane magnetized films of a predetermined composition are stacked in four layers.

In these film formation processes (film formation processes of a Ru substrate film, a CoPt in-plane magnetized film, and a Ru nonmagnetic intermediate layer), none of them were subjected to substrate heating. They were performed in room temperature film formation.

A hysteresis loop of each of the produced in-plane magnetized film multilayer structures in Examples 4 to 11 and 14 was measured using a vibrating magnetometer. From the measured hysteresis loop, a magnetic coercive force Hc (kOe) and remanent magnetization Mr (memu/cm³) were read. By multiplying the read remanent magnetization Mr (memu/cm³) by the total thickness of the CoPt in-plane magnetized films of the produced in-plane magnetized film multilayer structure, remanent magnetization per unit area Mrt (memu/cm²) of the produced in-plane magnetized film multilayer structure was calculated.

Further, in in-plane magnetized film multilayer structures of Examples 4 to 11 and 14, the in-plane direction average grain diameter of CoPt alloy magnetic crystal grains in the CoPt in-plane magnetized film which is a fourth film counted from the Si substarate side was measured by the measuring method described in (F) below.

The results of Examples 4 to 11 and 14 are shown in the following Table 3.

TABLE 3

| | Composition of target used for producing nonmagnetic intermediate layer | Thickness of nonmagnetic intermediate layer (nm) | Composition of target used for producing in-plane magnetized film | Composition of in-plane magnetized film | Thickness of in-plane magnetized film (nm) | | Thickness of Ru substrate film (nm) | In-plane direction average grain diameter of CoPt alloy magnetic crystal grains (nm) | Magnetic coercive force He (k0e) | Remanent magnetization per unit area Mrt (memu/cm²) |
|---|---|---|---|---|---|---|---|---|---|---|
| | | | | | Total thickness | Thickness of one layer | | | | |
| Example 14 | 100Ru | 2.0 | (Co-40Pt) -3vol%WO₃ | (Co-46.OPt) -3.0vol%WO₃ | 60 | 15 | 60 | 25.9 | 6.47 | 3.21 |
| Example 4 | 100Ru | 2.0 | (Co-40Pt) -5vol%WO₃ | (Co-46.OPt) -5.1vol%WO₃ | 60 | 15 | 60 | 24.4 | 7.52 | 2.55 |
| Example 5 | 100Ru | 2.0 | (Co-40Pt) -6vol%WO₃ | (Co-46.OPt) -6.1vol%WO₃ | 60 | 15 | 60 | 23.6 | 7.51 | 2.53 |
| Example 6 | 100Ru | 2.0 | (Co-40Pt) -7vol%WO₃ | (Co-46.OPt) -7.2vol%WO₃ | 60 | 15 | 60 | 23.7 | 7.48 | 2.51 |
| Example 7 | 100Ru | 2.0 | (Co-40Pt) -8vol%WO₃ | (Co-46.1Pt) -8.2vol%WO₃ | 60 | 15 | 60 | 23.2 | 7.51 | 2.49 |
| Example 8 | 100Ru | 2.0 | (Co-40Pt) -9vol%WO₃ | (Co-46.1Pt) -9.2vol%WO₃ | 60 | 15 | 60 | 22.6 | 7.33 | 2.31 |
| Example 9 | 100Ru | 2.0 | (Co-40Pt) -10vol%WO₃ | (Co-46.OPt) -10.3vol%WO₃ | 60 | 15 | 60 | 22.1 | 6.94 | 2.15 |
| Example 10 | 100Ru | 2.0 | (Co-40Pt) -15vol%WO₃ | (Co-46.1Pt) -15.5vol%WO₃ | 60 | 15 | 60 | 18.2 | 6.25 | 2.07 |
| Example 11 | 100Ru | 2.0 | (Co-40Pt) -20vol%WO₃ | (Co-46.2Pt) -20.6vol%WO₃ | 60 | 15 | 60 | 16.7 | 5.51 | 2.01 |

As can be seen from Table 3, each of in-plane magnetized film multilayer structures of Examples 4 to 11 and 14 is an in-plane magnetized film multilayer structure in which CoPt in-plane magnetized films having a thickness of 15 nm are stacked in four layers sandwiching a Ru nonmagnetic intermediate layer having a thickness of 2 nm. Each of the in-plane magnetized films of the in-plane magnetized film multilayer structures of Examples 4 to 11 and 14 contains the metal Co in an amount of 45 at% or more and 80 at% or less and the metal Pt in an amount of 20 at% or more and 55 at% or less relative to a total of metal components (Co, Pt) of the each of the in-plane magnetized films, and contains the oxide in an amount of 3 vol% or more and 25 vol% or less relative to a whole amount of the each of the in-plane magnetized film. The in-plane direction average grain diameter of CoPt alloy magnetic crystal grains of the CoPt in-plane magnetized film is 16.7 nm to 25.9 nm, which is included in the range of 15 nm or more and 30 nm or less. Therefore, the in-plane magnetized film multilayer structures of Examples 4 to 11 and 14 are within the scope of the present invention, and achieved magnetic performance of a magnetic coercive force Hc of 2.00 kOe or more and remanent magnetization per unit area Mrt of 2.00 memu/cm² or more by the room temperature film formation without heating the substrate.

The in-plane magnetized film multilayer structures of Examples 4 to 11 and 14 are within the scope of the present invention. As can be seen from Table 3, the smaller oxide (WO₃) content tends to have a larger coercive force Hc in the range of oxide (WO₃) content of 3.0 to 20.6 vol%. This is considered to be attributable to the fact that the smaller oxide (WO₃) content tends to increase the in-plane direction average grain diameter of CoPt alloy magnetic crystal grains in the in-plane magnetized film.

### (D) Study About the Effect of the Use of B₂O₃ as the Oxide and the Inclusion of Boron B as the Metal Components (Examples 12 and 13)

In Example 12, an in-plane magnetized filmmultilayer structure was prepared in the same manner as in Example 7 except that (Co-40Pt) -8vol%B₂O₃ sputtering target, which the oxide was replaced with B₂O₃ from WO₃ in the (Co-40Pt) -8vol%WO₃ sputtering target, was used, and the measurement was done in the same manner as in Example 7.

In Example 13, an in-plane magnetized filmmultilayer structure was prepared in the same manner as in Example 12 except that (Co-40Pt) -3B-8vol%B₂O₃ sputtering target, in which boron B of 3 at% was added as a metal component in the (Co-40Pt) -8vol%B₂O₃ sputtering target which was used for producing the in-plane magnetized films of the in-plane magnetized film multilayer structure of Example 12, was used, and the measurement was done in the same manner as in Example 12.

Those results are shown in Table 4 below, along with the results of Example 7.

TABLE 4

| | Composition of target used for producing nonmagnetic intermediate layer | Thickness of nonmagnetic intermediate layer (nm) | Composition of target used for producing in-plane magnetized film | Composition of in-plane magnetized film | Thickness of in-plane magnetized film (nm) | | Thickness of Ru substrate film (nm) | In-plane direction average grain diameter of CoPt alloy magnetic crystal grains (nm) | Magnetic coercive force Hc (kOe) | Remanent magnetization per unit area Mrt (memu / cm²) |
|---|---|---|---|---|---|---|---|---|---|---|
| | | | | | Total thickness | Thickness of one layer | | | | |
| Example 12 | 100Ru | 2.0 | (Co-40Pt) -8vol%B₂O₃ | (Co-46.1Pt) -10.0vol% B₂O₃ | 60 | 15 | 60 | 23.4 | 7.61 | 3.09 |
| Example 13 | 100Ru | 2.0 | (Co-40Pt)-3B -8vol% B₂O₃ | (Co-46.1Pt)-3B -10.0vol% B₂O₃ | 60 | 15 | 60 | 23.1 | 7.67 | 2.91 |
| Example 7 | 100Ru | 2.0 | (Co-40Pt) -8vol%WO₃ | (Co-46.1Pt) -8.2vol%WO₃ | 60 | 15 | 60 | 23.2 | 7.51 | 2.49 |

As can be seen from Table 4, by using in Example 12 (Co-40Pt)-8vol%B₂O₃ sputtering target, in which the oxide was replacedwithB₂O₃ fromWO₃ in the (Co-40Pt) -8vol%WO₃ sputtering target used for producing the in-plane magnetized filmmultilayer structure of Example 7, the obtained in-plane magnetized film multilayer structure improved magnetic coercive force Hc by about 1.3%, and improved remanent magnetization per unit area Mrt by about 24%.

Also, by using in Example 13 (Co-40Pt) -3B-8vol%B₂O₃ sputtering target, in which boron B of 3 at% was added as a metal component in the (Co-40Pt)-8vol%B₂O₃ sputtering target which was used for producing the in-plane magnetized films of the in-plane magnetized film multilayer structure of Example 12, the obtained in-plane magnetized film multilayer structure improved magnetic coercive force Hc by about 0.8%, and reduced remanent magnetization per unit area Mrt by about 6%.

### (E) Analysis of Composition of In-Plane Magnetized Films (Reference Examples 1 to 8)

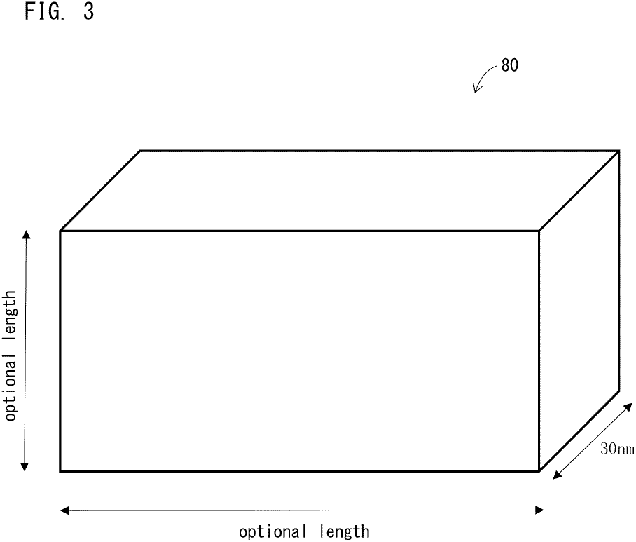

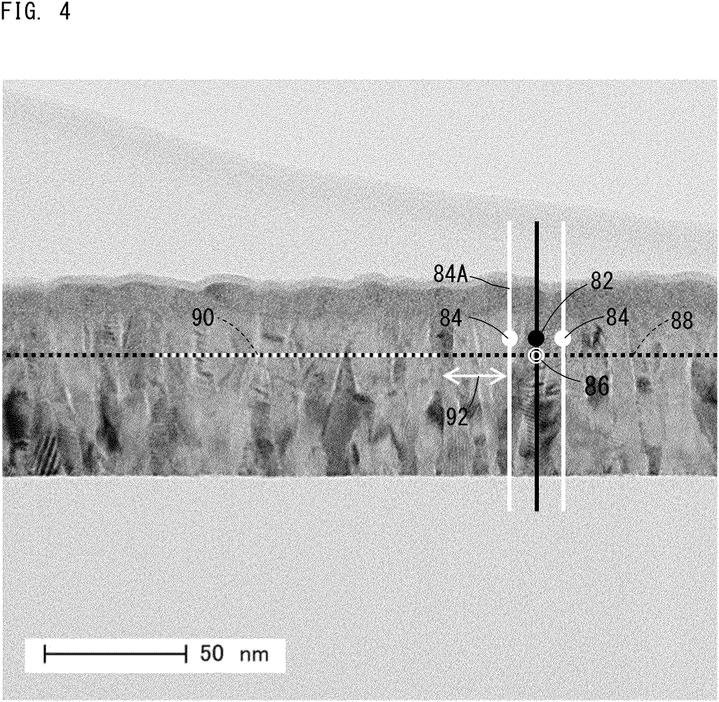

Compositional analysis of in-plane magnetized film of each of Reference Examples 1-8 was performed to determine the degree of deviation between the actual composition (composition obtained by compositional analysis) of the produced CoPt-WO₃ in-plane magnetized film and the composition of sputtering target used for producing the CoPt-WO₃ in-plane magnetized film. An outline of steps of a composition analysis method performed to the in-plane magnetized film of Reference Example 7 will be described, and thereafter concrete contents of each step will further be described.

[Outline of steps] Line analysis is performed to analyze the composition in a thickness direction of an in-plane magnetized film, and a portion having less variation in the composition is chosen from linearly analyzed portions in cross section in the thickness direction of the in-plane magnetized film (Steps 1 to 4). Then, auxiliary lines are drawn to the left and right in the in-plane direction of the in-plane magnetized film to be analyzed for composition so as to include an optional measurement point included in the portion having less variation in the composition, and line analysis is performed to analyze the composition in a linear region of 100 nm on the auxiliary lines (Step5). An average value of detected strengths at 167 measurement points is calculated on each detected element, to determine the composition of the in-plane magnetized film (Step 6). Steps 1 to 6 will be hereinafter described in the concrete.

[Step 1] An in-plane magnetized film the composition of which was to be analyzed is cut by parallel two planes in a direction (a thickness direction of the in-plane magnetized film) orthogonal to an in-plane direction, and thinning processing is performed by a FIB method (µ-sampling method) until the distance between the obtained two parallel cutting planes becomes about 30 nm. FIG. 3 schematically shows the shape of a thinned sample 80 after having been subjected to the thinning processing. As shown in FIG. 3, the shape of the thinned sample 80 is in an approximately rectangular parallelepiped shape. The distance between the two parallel cutting planes is about 30 nm, and the length of a side of the rectangular parallelepiped thinned sample 80 in the in-plane direction is about 30 nm, but the lengths of other two sides may be appropriately determined as long as the thinned sample 80 is observable by a scanning transmission electron microscope.

[Step 2] The cutting plane (the cutting plane of the in-plane magnetized film in the thickness direction) of the thinned sample 80 obtained in Step 1 is imaged using the scanning transmission electron microscope that allows observation with magnifying a length of 100 nm into 2 cm (observation at a magnification of two hundred thousand times), and an observation image is captured. The rectangular observation image is captured such that a line of a crossing portion of a topmost surface of the in-plane magnetized film to be observed and the cutting plane (the cutting plane in the thickness direction of the in-plane magnetized film) coincides with a longitudinal direction of the rectangular observation image. FIG. 4 shows an example (observation image of Referance Example 7) of the captured observation image. The observation image of the in-plane magnetized film was captured using H-9500 manufactured by Hitachi High-Tech Corporation.

[Step 3] An optional point (indicated by a black dot 82 in FIG. 4) included in the in-plane magnetized film is chosen from the observation image captured in Step 2, and positions (indicated by white dots 84 in FIG. 4) 10 nm away from the point to left and right in the longitudinal direction of the observation image are pointed. Line analysis for elemental analysis is performed in the thickness direction of the in-plane magnetized film so as to pass the point of the black dot 82, and line analysis for elemental analysis is performed in the thickness direction of the in-plane magnetized film so as to pass the points of the white dots 84. Thereby, line analysis (scanning from top to bottom) for elemental analysis is performed in the thickness direction of the in-plane magnetized film with respect to three lines (one line passing through the black dot 82 in the thickness direction and two lines passing through the white dots 84 in the thickness direction). At the time of performing the line analysis for elemental analysis, it is necessary to choose the point of the one black dot 82 and the points of the two white dots 84 such that a scanning range of the line analysis along the three lines corresponds to the entire range in the thickness direction of the in-plane magnetized film (when a target of composition analysis is an in-plane magnetized film multilayer structure, it is the entire range from an uppermost in-plane magnetized film to a lowermost in-plane magnetized film), in principle.

In composition analysis of the in-plane magnetized film, energy dispersive X-ray spectroscopy (EDX) was adopted as an element analysis technique, and JEM-ARM200F manufactured by JEOL Ltd. was used as an elemental analyzer. Concrete analysis conditions were as follows. That is, a Si-drift detector was used as an X-ray detector, an X-ray take-off angle was 21.9°, a solid angle was approximately 0.98 sr, a dispersive crystal generally appropriate to each element was used, a measurement time was 1 seconds/point, a scanning interval was 0.6 nm, and an irradiation beam diameter was 0.2 nmϕ. The conditions described in this paragraph may be hereinafter referred to as “analysis conditions of Step 3”.

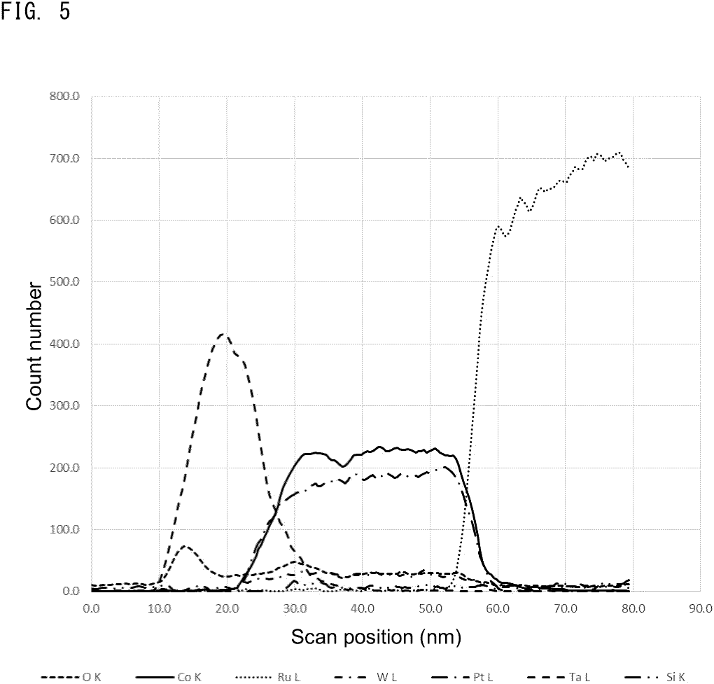

FIG. 5 shows a result of the line analysis (elemental analysis) performed along a black line (the line passing through the point of the black dot in the thickness direction of the in-plane magnetized film) in FIG. 4 (the observation image of Reference Example 7). In FIG. 5, a vertical axis represents the detection strength of each element, and a horizontal axis represents a scan position. Elements shown in an explanatory note of FIG. 5 are elements that have been confirmed with sufficient detection strengths. In Reference Example 7, the elements confirmed with sufficient detection strengths were Co, Pt, W, O, and Ru. In the composition analysis of Reference Example 7, a Kα1-ray was chosen to detect Co and O and a Lα1-ray was chosen to detect Pt, Ru, and W. Each detection strength was corrected by subtracting a detection strength of blank measurement measured in advance. In FIG. 4, a last end (lowermost end) of the line analysis is a Si substrate. In this portion, only Si and O which is due to surface oxidation are detected in theory. Accordingly, a detection value of an element other than Si and O detected in this portion is conceivable to be an unavoidable detection error value in the elemental analyzer. Thus, the detection strength shall represent the presence of the element only when the detection strength is higher than the detection error value.

Reference Example 7 is an in-plane magnetized film single-layer structure, and in Reference Example 7, the in-plane magnetized film having a thickness of 30 nm was formed by using a sputtering target whose composition is (Co-30Pt)-10vol%WO₃. A Ta layer having a thickness of 10 nm was formed on the uppermost layer to prevent oxidization of the in-plane magnetized film, and a sputtering target of 100 at% Ta was used to form the layer.

As can be seen from the result of line analysis shown in FIG. 5, Co, Pt, W, and O were mainly detected in the in-plane magnetized films, Ru was mainly detected in the substrate film, and Ta was mainly detected in the oxidation prevention layer. At the interface of each layer in contact with the in-plane magnetized film, sputtering heat during film formation partially confirms that the elements of each layer adjacent to the top and bottom are diffused to each other. However, as far as seen from the distribution of each primary element of the in-plane magnetized films, it was confirmed that film formation was performed as almost designed.

[Step 4] From the result of the line analysis (the line analysis for elemental analysis performed in the thickness direction of the in-plane magnetized film) performed in Step 3, an aggregation portion of measurement points having less variation in composition is chosen. The aggregation portion of the measurement points having less variation in composition is an aggregation portion of measurement points satisfying the following conditions a to c.

Condition a) The measurement points are measurement points of the line analysis along any of the three lines performed in Step 3, and where the sum of the detection strengths of Co and Pt exceeds 300 counts.

Condition b) When an X count represents the sum of the detection strengths of Co and Pt at the measurement point, and a Y count represents the sum of the detection strengths of Co and Pt at the next measurement point (a measurement point that is adjacent to and 0.6 nm downward away from the measurement point) after measurement is performed at the measurement point,

$$Y / X - 1 < 0.05$$

is satisfied.

Condition c) The measurement points are five or more consecutive measurement points that satisfy the conditions a and b.

The aggregation portion of the measurement points satisfying the conditions a to c contains five or more consecutive measurement points, and hence is in a linear area of 0.6 nm × 4 = 2.4 nm or more. Therefore, the aggregation portion of the measurement points satisfying the conditions a to c is a linear area of a range of 2.4 nm or more in which at least one of Co or Pt is stably detected.

[Step 5] An optional measurement point is chosen from the aggregation of the measurement points chosen in Step 4, as a reference point (indicated by a double white circle 86 in FIG. 4) for composition analysis of the in-plane magnetized film. Then, an auxiliary line (indicated by black broken line 88 in FIG. 4) is drawn to the left and right in the in-plane direction (longitudinal direction of observation image in FIG. 4) of in-plane magnetized film in which the composition analysis is performed so as to include the reference point, and the composition analysis is performed on a linear area of 100 nm (indicated by white broken line 90 in FIG. 4) on the auxiliary line under the same analysis conditions as that in Step 3. In order to avoid contamination caused by the above-mentioned line analysis in the thickness direction, white broken line 90, which is a target portion of the composition analysis, was set at a distance (indicated by white line 92 with arrows attached to both ends in FIG. 4) of 10 nm or more from the line analysis portion (white line 84A in FIG. 4) in the thickness direction. In the composition analysis, because line analysis is performed on the linear area of 100 nm at scanning intervals of 0.6 nm, analysis results are obtained at 167 measurement points in total.

[Step 6] An average value of detected strengths (count numbers) of 167 measurement points is calculated on each detected element. The ratio of the average values of the detected strengths (count numbers) of each detected elements coincides with the composition ratio of each element of the in-plane magnetized film.

In analysis by EDX, it is unavoidable that fluorescent X-rays of a light element such as oxygen (O) are absorbed by fluorescent X-rays of a heavy element such as platinum (Pt), but the light element such as oxygen (O) and the heavy element such as platinum (Pt) are mixed in the in-plane magnetized film according to the present invention. Therefore, as to oxygen (O), the composition of the in-plane magnetized film was determined on the assumption that a metal (W in Reference Example 7) that was present as an oxide was totally oxidized (into WO₃ in Reference Example 7) in an appropriate manner.

The compositions of sputtering target used for producing the in-plane magnetized film of Reference Examples 1 to 8 and the results of the analyses of composition for the in-plane magnetized films of Reference Examples 1 to 8 are shown in the following Tables 5.

TABLE 5

| | | |
|---|---|---|
| | Composition of sputtering target | Result of analysis of composition of in-plane magnetized film |
| Reference Example 1 | (Co-20Pt) -30vol%WO₃ | (Co-24.1Pt) -31.2vol%WO₃ |
| Reference Example 2 | (Co-20Pt) -30vol%WO₃ | (Co-24.5Pt)-30.7vol%WO₃ |
| Reference Example 3 | (Co-30Pt) -10vol%WO₃ | (Co-33.9Pt)-10.2vol%WO₃ |
| Reference Example 4 | (Co-30Pt) -10vol%WO₃ | (Co-33.6Pt)-9.8vol%WO₃ |
| Reference Example 5 | (Co-20Pt) -10vol%WO₃ | (Co-22.8Pt)-10.3vol%WO₃ |
| Reference Example 6 | (Co-45Pt) -10vol%WO₃ | (Co-52.4Pt) -10.5vol%WO₃ |
| Reference Example 7 | (Co-30Pt) -10vol%WO₃ | (Co-34.5Pt) -10.6vol%WO₃ |
| Reference Example 8 | (Co-40Pt) -20vol%WO₃ | (Co-46.7Pt) -21.0vol%WO₃ |

As shown in Table 5, there is a deviation between the composition of sputtering target and the composition of the in-plane magnetized film produced using the sputtering target, and therefore, this deviation is corrected to determine the composition of CoPt-WO₃ in-plane magnetized film in the Examples and Comparative Examples described in the above (A) to (C).

Note that, in Examples 12 and 13, boron (B) and B₂O₃ are added to the in-plane magnetized film, but boron (B) is a light element with a small atomic number and cannot be detected by analysis in EDX. Therefore, in the composition of the in-plane magnetized films in Examples 12 and 13, though the composition ratios of Co and Pt can be determined, the content of boron (B) or B₂O₃ can not be determined.

In FIG. 4, circles, straight lines, etc. indicated by the reference signs 82, 84, 84A, 86, 88, 90, 92 are added for convenience in explaining the composition analysis method, and do not correspond to the actual measurement portion.

### (F) Measuring Method of In-Plane Direction Average Grain Diameter of CoPt Alloy Magnetic Crystal Grains in the CoPt In-Plane Magnetized Film (Examples 1 to 14 and Comparative Examples 1 and 2)

In Examples 1 to 14 and Comparative Examples 1 and 2, in-plane direction average grain diameter of CoPt alloy magnetic crystal grains in the CoPt in-plane magnetized film was measured. Hereinafter, after the outline of the procedure of the measuring method performed is described, the contents of each procedure will be described specifically. Here, description will be made based on the measurement results in Example 1. In the explanation here, a CoPt alloy magnetic crystal grain is described as “a magnetic grain”.

[Outline of steps] Line analysis is performed to analyze the composition in a thickness direction of an in-plane magnetized film, and a portion having less variation in the composition is chosen from linearly analyzed portions in cross section in the thickness direction of the in-plane magnetized film (Steps 1 to 4). Then, the thinning treatment is performed so that the portion where the variation of the composition is small becomes the outermost layer (the surface which becomes the outermost layer is the surface in the in-plane direction). The plane observation images are obtained for two or more portions of in-plane planes of the outermost layer at scanning transmission electron microscope (Step 5). In each of the obtained planar observation images, four straight lines of 150 nm in length are drawn horizontally and vertically so that nine squares of 50 nm in length are drawn, and the grain size is measured for a total of eight straight lines by the cut-off method. This grain size measurement is performed on two or more planar observation images, and the averaged result of the grain size measurement for all planar observation images is used as the average grain diameter in the in-plane direction (Step 6).

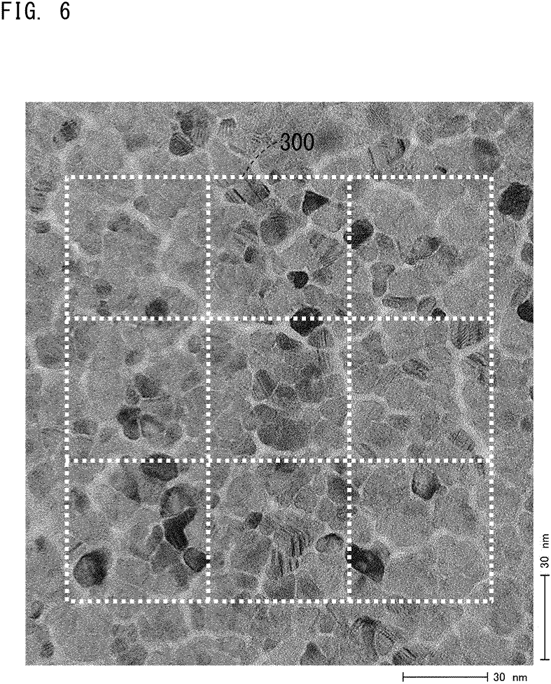

The method of selecting a place with little variation in composition by steps 1 to 4 is the same as steps 1 to 4 of “(E) Analysis of composition of in-plane magnetized films (Reference Examples 1 to 8)” described above, and therefore the content of steps 5 and 6 will be described specifically below.

[Step 5] The thinning process is carried out so that the portion (the portion along the thickness of in-plane magnetized film) with little compositional variation selected in steps 1 to 4 becomes the outermost layer. Imaging the in-plane surface of the outermost layer of the portion where the thickness of the in-plane magnetized film is approximately 10 to 20 nm after the thinning process using scanning transmission electron microscope so as to enlarge the length of 30 nm to 2 cm, converting the length of 30 nm to the number of pixels indicated by 472 pixels, and obtaining the digital data of the plane observation image. Digital data of the plane observation image is acquired at least at two or more portions of the same sample subjected to the thinning processing. FIG. 6 shows an example of the obtained plane observation image (the plane observation image of Example 1). The plane observation image of in-plane magnetized film was obtained using H-9500 manufactured by Hitachi High-Tech Corporation, and observed at an accelerating voltage of 200 kV. Note that since oxide, which is a nonmagnetic grain boundary material, contains a large amount of oxygen, which is a light element, it is easy to be imaged in a relatively white color, and a magnetic layer, which contains a large amount of Pt, which is a heavy element, is easy to be imaged in a relatively black color, the contrast and lightness are appropriately adjusted in view of these factors. By appropriately adjusting the contrast and brightness, it is possible to obtain a plane observation image as shown in FIG. 6, for example.

[Step 6] On each plane observation image obtained in Step 5, four lines 300 each having a length of 150 nm are drawn vertically and horizontally so that nine squares each having a length of 50 nm are drawn, and grain diameter measurements are performed on eight lines 300 (shown by white broken line in FIG. 6) by the cutting method, which will be described later, and for each of these eight lines 300, average grain diameter is obtained, and average grain diameter obtained by averaging average grain diameter obtained on each of the eight lines 300 is defined as average grain diameter in this plane observation image (FIG. 6). Then, the above-mentioned grain diameter measurements are performed on all of the plane observation image obtained in the step 5, and average grain diameter obtained by averaging all of average grain diameter of the plane observation image obtained in the step 5 is taken as the in-plane direction average grain diameter in in-plane magnetized film of the samples.

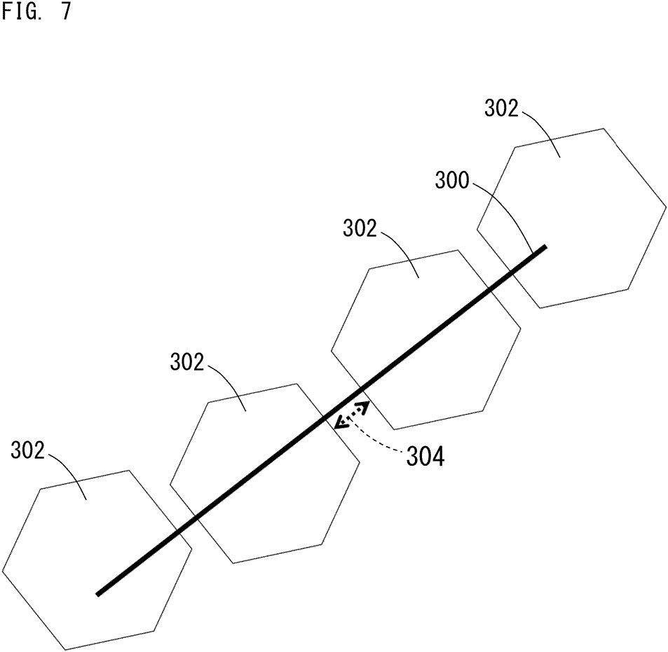

The cutting method will be specifically described with reference to a schematic diagram of a plane observation image shown in FIG. 7.

First, magnetic grain 302 existing in the plane observation image shown in FIG. 7 is identified by the methods described later, and the regions in the plane observation image are classified into magnetic grain 302 and regions other than magnetic grain 302 (i.e., the regions of the grain boundary material). A value obtained by dividing the length L of the straight line 300, which is shown by black line in FIG. 7, by the number n of magnetic grain 302 contacting the straight line 300 is defined as the in-plane direction average grain diameter of the straight line 300.

The image analysis software ImageJ1. 44p is used to specify the image of a magnetic grain. The image data of the plane observation image (FIG. 6) is read into the image analysis software, and the light and dark intensities of each of one pixel squares in the plane observation image (FIG. 6) are sieved from 0 to 255 stages (0 is white and 255 is black). A binarization process (a pixel where the light and dark intensities are 90 or more is set as “1”, and a pixel where the light and dark intensities are 89 or less is set as “0”) is performed in which a portion where the light and dark intensities are 90 or more is judged as a part of a magnetic grain.

Next, as shown in FIG. 6, four straight lines 300 each having a length of 150 nm are drawn vertically and horizontally so that nine squares each having a length of 50 nm are drawn on the plane observation image on which the binarization processig was performed, and eight straight lines 300 are drawn in total. Then, for the pixel in contact with the straight line 300, a value (1 or 0) obtained by binarization processing is obtained.

Then, finally, as a correction, only when the pixel changing from “1” to “0” is included and “0” continues continuously for 7 or more pixels, the value of those pixels is maintained as “0”, and when “0” does not continue for 7 or more pixels continuously, correction is performed to change the value of those pixels from “0” to “1”. This is based on the idea that adj acent magnetic grain 302 are magnetically coupled when the spacing 304 between adjacent magnetic grain 302 (i.e., crystal grain boundary widths due to non-magnetic materials) is less than or equal to 6 pixels in length ((30 nm / 472 pixels) × 6 pixels = about 0.38 nm) (the idea that adjacent magnetic grains 302 can be considered magnetically as one particle when the spacing 304 between adjacent magnetic grains 302 is less than or equal to about 0.38 nm).

In FIG. 6, straight lines indicated by the reference sign 300 are added for convenience in explaining the measuring method of in-plane direction average grain diameter of magnetic grains, and do not correspond to the actual measurement portion.

### INDUSTRIAL APPLICABILITY

The in-plane magnetized film, the in-plane magnetized film multilayer structure, the hard bias layer, the magnetoresistive effect element, and the sputtering target according to the present invention can achieve magnetic performance of a magnetic coercive force Hc of 2.00 kOe or more and remanent magnetization per unit area Mrt of 2.00 memu/cm² or more, without performing film formation with heating, and hence have industrial applicability.

Reference Signs List

| | |
|---|---|
| 10 | in-plane magnetized film |
| 12, 24 | magnetoresistive effect element |
| 14, 26 | hard bias layer |
| 16, 28 | free magnetic layer |
| 20 | in-plane magnetized film multilayer structure |
| 22 | nonmagnetic intermediate layer |
| 50 | insulating layer |
| 52 | pinned layer |
| 54 | barrier layer |
| 80 | thinned sample |
| 82 | black dot (optional point included in in-plane magnetized film) |
| 84 | white dot (points at positions 10 nm away from black dot 82 to left and right in longitudinal direction of observation image) |
| 84A | white line |
| 86 | double white circle (reference point for composition analysis of in-plane magnetized film) |
| 88 | black broken line (an auxiliary line drawn from double white circle 86 (reference point) in longitudinal direction of observation image) |
| 90 | white broken line (100 nm linear area on black broken line 88 (auxiliary line)) |
| 92 | white line with arrows at both ends ( indicating distances |
| | of 10 nm or more from white line 84A) |
| 300 | straight line |
| 302 | magnetic grain |
| 304 | spacing between adjacent magnetic grain 302 (crystal grain boundary widths due to non-magnetic materials) |

1. An in-plane magnetized film for use as a hard bias layer of a magnetoresistive effect element, the in-plane magnetized film comprising metal Co, metal Pt, and an oxide, wherein
the in-plane magnetized film has a thickness of 20 nm or more and 80 nm or less,
the in-plane magnetized film contains the metal Co in an amount of 45 at% or more and 80 at% or less and the metal Pt in an amount of 20 at% or more and 55 at% or less relative to a total of metal components of the in-plane magnetized film,
the in-plane magnetized film contains the oxide in an amount of 3 vol% or more and 25 vol% or less relative to a whole amount of the in-plane magnetized film, and
an in-plane direction average grain diameter of magnetic crystal grains of the in-plane magnetized film is 15 nm or more and 30 nm or less.

2. The in-plane magnetized film according to claim 1, having a granular structure constituted of CoPt alloy crystal grains and a crystal grain boundary made of the oxide.

3. The in-plane magnetized film according to claim 1, wherein the oxide contains at least one of a Ti oxide, a Si oxide, a W oxide, a B oxide, a Mo oxide, a Ta oxide, and a Nb oxide.

4. The in-plane magnetized film according to claim 1, wherein the in-plane magnetized film contains boron in an amount of 0.5 at% or more and 3.5 at% or less relative to a total of metal components of the in-plane magnetized film.

5. An in-plane magnetized film multilayer structure for use as a hard bias layer of a magnetoresistive effect element, the in-plane magnetized film multilayer structure comprising:
a plurality of in-plane magnetized films; and
a nonmagnetic intermediate layer a crystal structure of which is a hexagonal closest packed structure, wherein
the nonmagnetic intermediate layer is disposed between the in-plane magnetized films, and the in-plane magnetized films adjacent across the nonmagnetic intermediate layer are coupled by a ferromagnetic coupling,
each of the in-plane magnetized films
contains metal Co, metal Pt, and an oxide,
contains the metal Co in an amount of 45 at% or more and 80 at% or less and the metal Pt in an amount of 20 at% or more and 55 at% or less relative to a total of metal components of the each of the in-plane magnetized film, and
contains the oxide in an amount of 3 vol% or more and 25 vol% or less relative to a whole amount of the each of the in-plane magnetized film,
an in-plane direction average grain diameter of magnetic crystal grains of the in-plane magnetized film is 15 nm or more and 30 nm or less, and
a total thickness of the plurality of in-plane magnetized films is 20 nm or more.

6. An in-plane magnetized film multilayer structure for use as a hard bias layer of a magnetoresistive effect element, the in-plane magnetized film multilayer structure comprising:
a plurality of in-plane magnetized films; and
a nonmagnetic intermediate layer, wherein
the nonmagnetic intermediate layer is disposed between the in-plane magnetized films, and the in-plane magnetized films adjacent across the nonmagnetic intermediate layer are coupled by a ferromagnetic coupling,
each of the in-plane magnetized films
contains metal Co, metal Pt, and an oxide,
contains the metal Co in an amount of 45 at% or more and 80 at% or less and the metal Pt in an amount of 20 at% or more and 55 at% or less relative to a total of metal components of the each of the in-plane magnetized films, and
contains the oxide in an amount of 3 vol% or more and 25 vol% or less relative to a whole amount of the each of the in-plane magnetized films,
an in-plane direction average grain diameter of magnetic crystal grains of the each of the in-plane magnetized films is 15 nm or more and 30 nm or less, and
the in-plane magnetized film multilayer structure has a magnetic coercive force of 2.00 kOe or more and remanent magnetization per unit area of 2.00 memu/cm² or more.

7. The in-plane magnetized film multilayer structure according to claim 5, wherein the nonmagnetic intermediate layer is made of Ru or a Ru alloy.

8. The in-plane magnetized film multilayer structure according to claim 5, wherein each of the in-plane magnetized films is configured to have a granular structure constituted of CoPt alloy crystal grains and a crystal grain boundary made of the oxide.

9. The in-plane magnetized film multilayer structure according to claim 5, wherein the oxide contains at least one of a Ti oxide, a Si oxide, a W oxide, a B oxide, a Mo oxide, a Ta oxide, and a Nb oxide.

10. The in-plane magnetized film multilayer structure according to claim 5, wherein a thickness per one layer of the in-plane magnetized films is 5 nm or more and 30 nm or less.

11. A hard bias layer comprising the in-plane magnetized film according to claim 1.

12. A magnetoresistive effect element comprising the hard bias layer according to claim 11.

13. A sputtering target for use in forming an in-plane magnetized film for use as at least part of a hard bias layer of a magnetoresistive effect element by room temperature film formation, wherein
the sputtering target
contains metal Co, metal Pt, and an oxide,
contains the metal Co in an amount of 50 at% or more and 85 at% or less and the metal Pt in an amount of 15 at% or more and 50 at% or less relative to a total of metal components of the sputtering target, and
contains the oxide in an amount of 3 vol% or more and 25 vol% or less relative to a whole amount of the sputtering target, and
the in-plane magnetized film to be formed has a magnetic coercive force of 2.00 kOe or more and remanent magnetization per unit area of 2.00 memu/cm² or more.

14. The in-plane magnetized film multilayer structure according to claim 6, wherein the nonmagnetic intermediate layer is made of Ru or a Ru alloy.

15. The in-plane magnetized film multilayer structure according to claim 6, wherein each of the in-plane magnetized films is configured to have a granular structure constituted of CoPt alloy crystal grains and a crystal grain boundary made of the oxide.

16. The in-plane magnetized film multilayer structure according to claim 6, wherein the oxide contains at least one of a Ti oxide, a Si oxide, a W oxide, a B oxide, a Mo oxide, a Ta oxide, and a Nb oxide.

17. The in-plane magnetized film multilayer structure according to claim 6, wherein a thickness per one layer of the in-plane magnetized films is 5 nm or more and 30 nm or less.

18. A hard bias layer comprising the in-plane magnetized film multilayer structure according to claim 5.

19. A hard bias layer comprising the in-plane magnetized film multilayer structure according to claim 6.

20. A magnetoresistive effect element comprising the hard bias layer according to claim 18.

21. A magnetoresistive effect element comprising the hard bias layer according to claim 19.
